(19) United States
(12) Patent Application Publication
(10) Pub. No.: US 2026/0338844 A1
(43) Pub. Date: Oct. 29, 2026

(54) WIDE-AREA MONITORING SYSTEM FOR WIDE-BAND OSCILLATION AND METHOD FOR LOCATING SOURCE OF WIDE-BAND OSCILLATION

(71) Applicant: ELECTRIC POWER RESEARCH INSTITUTE, CHINA SOUTHERN POWER GRID, Guangzhou, Guangdong (CN)

(72) Inventors: Wei WU, Guangzhou, Guangdong (CN); Baorong ZHOU, Guangzhou, Guangdong (CN); Chao HONG, Guangzhou, Guangdong (CN); Hong RAO, Guangzhou, Guangdong (CN); Qi GUO, Guangzhou, Guangdong (CN); Xipeng CAI, Guangzhou, Guangdong (CN); Dehui ZENG, Guangzhou, Guangdong (CN); Yuming LIU, Guangzhou, Guangdong (CN)

(73) Assignee: ELECTRIC POWER RESEARCH INSTITUTE, CHINA SOUTHERN POWER GRID, Guangzhou, Guangdong (CN)

(21) Appl. No.: 18/995,471

(22) PCT Filed: Mar. 13, 2024
(86) PCT No.: PCT/CN2024/081329

§ 371 Date: Jan. 16, 2025

(30) Foreign Application Priority Data
Oct. 24, 2023 (CN) 202311377961.X

(51) Int. Cl. G01R 23/163

(52) U.S. Cl. CPC G01R 23/163

(57) ABSTRACT

A wide-area monitoring system for wide-band oscillation and a method for locating a source of wide-band oscillation are provided. The system includes: a plurality of signal sensing modules configured to acquire electrical signals of measured points; a plurality of wide-band measurement devices configured to perform spectrum analysis based on the electrical signals and generate oscillation alarm information based on spectrum analysis results, and to start wave recording in response to wave recording instructions, to generate wave recording files for a same time section, and upload the wave recording files and spectrum analysis results; a wide-band measurement master station configured to determine whether there is a wide-band oscillation risk in a power system according to the oscillation alarm information, send the wave recording instructions to all of the wide-band measurement devices when there is the wide-band oscillation risk, and locate an oscillation source based on the spectrum analysis results.

### CROSS REFERENCE OF RELATED APPLICATION

The present application claims priority to Chinese Patent Application No. 202311377961.X, titled “wide-area monitoring system for wide-band oscillation and method for locating source of wide-band oscillation”, filed on Oct. 24, 2023 with the Chinese Patent Office, which is incorporated herein by reference in its entirety.

### FIELD

The present disclosure relates to the technical field of stability of a power system, and in particular to a wide-area monitoring system for wide-band oscillation and a method for locating a source of wide-band oscillation.

### BACKGROUND

A traditional power system is equipped with a Supervisory Control and Data Acquisition (SCA/DA) and a Wide Area Measurement System (WAMS), which mainly focus on the measurement of power frequency phasors. Signals in other frequency bands are mostly filtered out by band-pass filters. However, with the development of power systems, especially new energy technologies, more and more new energy units and new transmission technologies will be integrated to the power system.

Taking offshore wind turbines as an example, the Voltage Source Converter Based High Voltage Direct Current (VSC-HVDC) has gradually become the mainstream choice for long-distance offshore wind power transmission. However, the interaction between the power electronic converter of the offshore wind turbine and the VSC-HVDC will cause wide-band oscillations with frequencies ranging from a few Hz to thousands of Hz. As the scale of offshore wind farms continues to expand, the problem of wide-band oscillations has become increasingly prominent, seriously affecting the safety and stability of the power systems, and becoming an important factor restricting the effective consumption of renewable energy such as the offshore wind power.

Therefore, the wide-area measurement system configured in the traditional power system cannot meet the measurement frequency band requirements of wide-band measurement. There is an urgent need for wide-area monitoring technology that supports monitoring of wide-band oscillation events to maintain the stability of the power systems.

### SUMMARY

The object of the present disclosure is to address at least one of the above technical deficiencies, especially the problem that wide-area monitoring system in the conventional art does not support monitoring of wide-band oscillation.

In a first aspect, the present disclosure provides a wide-area monitoring system for wide-band oscillation, including:
a plurality of signal sensing modules, which are configured to acquire electric signals of measured points;
a plurality of wide-band measurement devices, which are connected to the signal sensing modules, and are configured to perform spectrum analysis based on the electrical signals acquired by each of the signal sensing modules and generate oscillation alarm information based on spectrum analysis results, and are also configured to start wave recording in response to wave recording instructions, to generate wave recording files for a same time section, and upload the wave recording files and the spectrum analysis results; and
a wide-band measurement master station, which is communicatively connected to each of the wide-band measurement devices, and is configured to determine whether there is a wide-band oscillation risk in a power system based on the oscillation alarm information uploaded by each of the wide-band measurement devices, send the wave recording instructions to all of the wide-band measurement devices when it is determined that there is the wide-band oscillation risk, and locate an oscillation source based on the spectrum analysis results fed back by each of the wide-band measurement devices.

In an embodiment, the wide-band measurement devices are configured to determine a content of each harmonic in the electrical signals based on the spectrum analysis results, and generate the oscillation alarm information when the content exceeds a corresponding content threshold, and send the oscillation alarm information to the wide-band measurement master station.

In an embodiment, the wide-band measurement master station is configured to send the content threshold to each of the wide-band measurement devices.

In an embodiment, the wide-band measurement devices are further configured to sample the electrical signals to obtain a waveform sequence corresponding to the electrical signals, and upload the waveform sequence to the wide-band measurement master station.

In an embodiment, the wide-band measurement master station is communicatively connected to each of the wide-band measurement devices through a 5G network, the spectrum analysis results, the waveform sequence and the wave recording instructions are transmitted through an uRLLC protocol, and the wave recording files and the content threshold are transmitted through an eMBB protocol.

In a second aspect, the embodiment of the present disclosure provides a method for locating a source of wide-band oscillation, applied to the wide-band measurement master station in the wide-area monitoring system for wide-band oscillation described in any one of the above embodiments, including:
determining whether there is the wide-band oscillation risk in a power system based on the oscillation alarm information uploaded by each of the wide-band measurement devices;
sending the wave recording instructions to all of the wide-band measurement devices when it is determined that there is the wide-band oscillation risk; the wave recording instruction is to instruct the wide-band measurement devices to perform wave recording to generate the wave recording files for the same time section, and upload the wave recording files and the spectrum analysis results to the wide-band measurement master station; and
locating the oscillation source based on the spectrum analysis results fed back by each of the wide-band measurement devices.

In an embodiment, determining whether there is the wide-band oscillation risk in the power system based on the oscillation alarm information uploaded by each of the wide-band measurement devices includes:

determining that there is the wide-band oscillation risk in the power system when an amount of the received oscillation alarm information is greater than a determination threshold.

In an embodiment, locating the oscillation source based on the spectrum analysis results fed back by each of the wide-band measurement devices includes:
performing data concatenation on the spectrum analysis results fed back by each of the wide-band measurement devices to obtain a wide-area wide-band spectrum information set; and
locating the oscillation source based on the wide-area wide-band spectrum information set.

In an embodiment, performing data concatenation on the spectrum analysis results fed back by each of the wide-band measurement devices to obtain the wide-area wide-band spectrum information set includes:

performing data concatenation on the spectrum analysis results fed back by each of wide-band measurement devices according to topological connection relationship between the measured points corresponding to each of the wide-band measurement devices, to obtain the wide-area wide-band spectrum information set.

In an embodiment, locating the oscillation source based on the wide-area wide-band spectrum information set includes:
traversing each harmonic in target frequency band range, and determining traversed harmonic as a target harmonic;
for a current target harmonic, selecting any one node from nodes in the power system as a target node;
performing Norton equivalence on the power system based on the target node;
determining, based on an equivalent model, a first equivalent impedance on a first side and a second equivalent impedance on a second side of the target node;
determining a first current and a second current based on the wide-area wide-band spectrum information set, the first current is defined as a current component of the target harmonic on the first side of the target node, and the second current is defined as a current component of the target harmonic on the second side of the target node;
determining an inflow side of oscillation power of the target harmonic as the first side or the second side, based on the first current, the first equivalent impedance, the second current, and the second equivalent impedance;
determining whether the inflow side corresponding to the current target node has changed from the inflow side corresponding to a previous target node;
when the inflow side corresponding to the current target node has not changed from the inflow side corresponding to the previous target node, determining a node connected to the current target node on the inflow side as a new target node, and returning to step of performing Norton equivalence on the power system based on the target node to proceed;
when the inflow side corresponding to the current target node has changed from the inflow side corresponding to a previous target node, determining that the oscillation source of the target harmonic is located between the current target node and the previous target node.

In an embodiment, determining the inflow side of oscillation power of the target harmonic as the first side or the second side, based on the first current, the first equivalent impedance, the second current and the second equivalent impedance includes:
determining a product of the first current and the first equivalent impedance as a first product;
determining a product of the second current and the second equivalent impedance as a second product;
when an absolute value of the first product is greater than an absolute value of the second product, determining the inflow side as the first side;
when the absolute value of the first product is smaller than the absolute value of the second product, determining the inflow side as the second side.

It can be seen from the above technical solutions that the embodiments of the present disclosure have the following advantages.

Based on any of the above embodiments, the function of wide-area monitoring for wide-band oscillations is realized by the functional modules used for signal sensing, wide-band measurement, and management master station. Among them, the wide-band measurement device can timely detect the harmonic oscillation risk at the measured point by performing spectrum analysis on the electrical signal, and report it to the wide-band measurement master station in time. The wide-band measurement master station can thus determine the harmonic oscillation situation of the entire power system based on the oscillation alarm information, and when it is determined that there is a wide-band oscillation risk, instruct all of the wide-band measurement devices to start wave recording synchronously, so as to facilitate the subsequent further analysis of the state of the power system when the wide-band oscillation risk occurs based on the wave recording files, and the oscillation source can be located based on the spectrum analysis results. The system has a clear structure, distinct levels, and strong feasibility in engineering applications. It is particularly suitable for wide-area monitoring of wide-band oscillation in offshore wind power grid-integration scenarios.

### BRIEF DESCRIPTION OF THE DRAWINGS

In order to more clearly describe the technical solutions in the embodiments of the present disclosure or the technical solutions in the conventional art, drawings to be used in the description of the embodiments of the present disclosure or the conventional art are briefly described hereinafter. It is apparent that the drawings described below are merely used for describing a part of the embodiments of the present disclosure, and those skilled in the art may obtain other drawings according to these provided drawings without any creative effort.

FIG. 1 is a schematic structure diagram of a wide-area monitoring system for wide-band oscillation provided by an embodiment of the present disclosure;

FIG. 2 is a schematic diagram of a communication structure of the wide-area monitoring system for wide-band oscillation provided by an embodiment of the present disclosure;

FIG. 3 is a schematic flowchart illustrating a method for locating the source of wide-band oscillation provided by an embodiment of the present disclosure; and

FIG. 4 is a schematic diagram showing the principle of performing Norton equivalence based on a target node in an embodiment of the present disclosure.

### DETAILED DESCRIPTION OF THE EMBODIMENTS

The technical solutions in the embodiments of the present disclosure will be described clearly and completely hereinafter in conjunction with the accompanying drawings in the embodiments of the present disclosure. It is apparent that the described embodiments are only some embodiments of the present disclosure, rather than all embodiments. Based on the embodiments in the present disclosure, all other embodiments obtained by those of ordinary skill in the art without creative efforts fall within the scope of protection of the present disclosure.

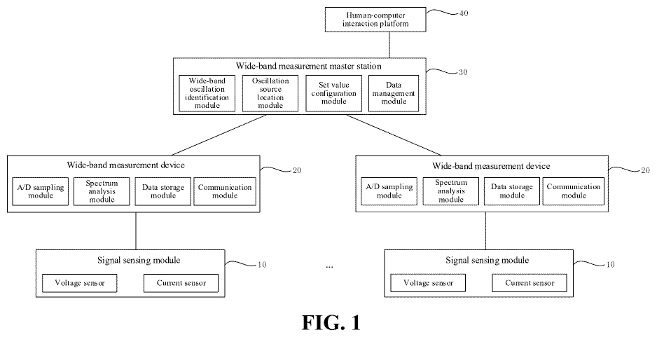

Please refer to FIG. 1. The present disclosure provides a wide-area monitoring system for wide-band oscillation, which includes a plurality of signal sensing modules 10, a plurality of wide-band measurement devices 20 and a wide-band measurement master station 30.

Among them, the signal sensing module 10 is configured to acquire the electrical signal of a measured point. It can be understood that the electrical signal mentioned here includes a current signal and a voltage signal. The signal sensing module 10 may include a current sensor and a voltage sensor. After acquiring the electrical signal, the signal sensing module 10 outputs the electrical signal to the corresponding wide-band measurement device 20. The selection of the measured point can be carried out according to the needs of wide-area monitoring and the relevant regulations of a power system. Generally, each node of the power system and the lines on both sides of the node can be selected as the measured point.

The wide-band measurement device 20 is connected to the signal sensing module 10, and is configured to perform spectrum analysis based on the electrical signals acquired by each signal sensing module 10, and generate oscillation alarm information based on the spectrum analysis results. It can be understood that spectrum analysis refers to the extraction of harmonic components of electrical signals using a preset algorithm, so as to obtain phasor information such as the amplitude and phase of each harmonic contained in the electrical signal. An A/D sampling module and a spectrum analysis module can be configured in the wide-band measurement device 20. The A/D sampling module samples the analog electrical signal output by the signal sensing module 10 and converts it into a corresponding waveform sequence. The A/D sampling module then outputs the waveform sequence to the spectrum analysis module, which performs spectrum analysis based on the waveform sequence and the preset algorithm to obtain the expressions for each harmonic component in the current signal and the voltage signal, thereby extracting the amplitude, the phase, etc. of each harmonic. In some embodiments, the preset algorithm can be a fast Fourier transform algorithm, a wavelet transform and its improved algorithm, or a Hilbert-Huang transform algorithm, etc., as long as the harmonics can be accurately extracted within the target frequency band range.

Due to the inclusion of the phasor information of each harmonic of the electrical signal within the target frequency band range in the spectrum analysis, and all of the harmonics other than the fundamental wave may affect the system stability in the power system. Therefore, based on the spectrum analysis results, the wide-band measurement device 20 can detect in real time whether harmonic oscillation occurs at the measured point it monitors, and send oscillation alarm information to the wide-band measurement master station 30 in time when it occurs. The wide-band measurement master station 30 is communicatively connected to each wide-band measurement device 20, determines whether there is a wide-band oscillation risk in the power system based on the oscillation alarm information uploaded by each wide-band measurement device 20, and sends a wave recording instruction to all of the wide-band measurement devices 20 when it is determined that there is a wide-band oscillation risk, to instruct all of the wide-band measurement devices 20 to start wave recording at the same time, to record the waveforms and data of some fault-related characteristic quantities in the power system when the oscillation fault occurs. Generally speaking, in addition to the waveforms of the current signal and the voltage signal, the wave recording files also record data related to the action sequence, system frequency, active power, reactive power, negative sequence current, zero sequence current, negative sequence voltage, zero sequence voltage, etc. of the protection and safety automatic devices. These data can be used to analyze the process and impact of harmonic oscillation and the action of protection devices and so on. The wide-band measurement device 20 shown in FIG. 1 is further provided with a data storage module for storing the data or processing results required for the wide-band measurement device 20 to work and acquired as needed. The wide-band measurement device 20 can also communicate with the wide-band measurement master station 30 through the communication module.

The wide-band measurement master station 30 locates the oscillation source based on the spectrum analysis results fed back by each wide-band measurement device 20. When the harmonic component with harmonic oscillation problem detected by the wide-band measurement device 20 is used as the target harmonic, the oscillation source location is used to find the source of the target harmonic from the power system. For example, when the third harmonic is found to have a harmonic oscillation problem, the third harmonic is used as the target harmonic, and the oscillation source location is used to find the location of the source of the third harmonic from the power system. In some embodiments, in order to comprehensively analyze the harmonic situation of the power system, all harmonics within the target frequency band monitored by the wide-area monitoring system for wide-band oscillation can also be selected as target harmonics.

Specifically, a wide-band oscillation identification module, an oscillation source location module, a set value configuration module and a data management module are provided in the wide-band measurement master station 30. Wherein, the wide-band oscillation identification module is configured to determine whether there is a wide-band oscillation risk in the power system based on the oscillation alarm information uploaded by each wide-band measurement device 20, and send a wave recording instruction to all of the wide-band measurement devices 20 when it is determined that there is a wide-band oscillation risk. The oscillation source location module is configured to locate the oscillation source based on the spectrum analysis results fed back by each wide-band measurement device 20. The set value configuration module is configured to send the set value required for some determination conditions to each wide-band measurement device 20, as well as to configure the set value required for some determination conditions needed for its own operation. The data management module is configured to uniformly manage the data generated by the wide-band measurement master station 30 itself and the data reported by each wide-band measurement device 20.

In order to facilitate the operation, observation, monitoring, control, etc. of the staff in the wide-band measurement master station 30, the wide-band measurement master station 30 is further deployed with a human-computer interaction platform 40. The staff can perform data visualization, data query, data analysis, remote control, and other operations at the wide-band measurement master station 30 through the human-computer interaction platform 40.

Based on the wide-area monitoring system for wide-band oscillation in the embodiment, the wide-area monitoring function for wide-band oscillation is realized through signal sensing, wide-band measurement, and management master station functional modules. Wherein, the wide-band measurement device 20 can timely detect the harmonic oscillation risk at the measured point by performing spectrum analysis on the electrical signal, and report it to the wide-band measurement master station 30 in time. The wide-band measurement master station 30 can thus determine the harmonic oscillation situation of the entire power system based on the oscillation alarm information, and when it is determined that there is a wide-band oscillation risk, instruct all of the wide-band measurement devices 20 to start wave recording synchronously, so as to facilitate the subsequent further analysis of the state of the power system when the wide-band oscillation risk occurs based on the wave recording file, and the oscillation source can be located based on the spectrum analysis results. The system has a clear structure, distinct levels, and strong feasibility in engineering applications, and is particularly suitable for wide-area monitoring for wide-band oscillation in offshore wind power grid-integration scenarios.

In one embodiment, the wide-band measurement device 20 is configured to determine the content of each harmonic in the electrical signal based on the spectrum analysis results, and generate the oscillation alarm information when the content exceeds the corresponding content threshold, and send the oscillation alarm information to the wide-band measurement master station 30. It can be understood that when the wide-band measurement device 20 finds that there is the harmonic content exceeding the threshold in the measured point, the entire system may encounter wide-band oscillation. Therefore, when the wide-band measurement device 20 finds that there is the harmonic content exceeding the threshold based on the spectrum analysis results and the content threshold corresponding to each harmonic content, the wide-band measurement device 20 sends the oscillation alarm information to the wide-band measurement master station 30. In some embodiments, the wide-band measurement master station 30 is configured to send the content threshold to each wide-band measurement device 20. That is, the wide-band measurement master station 30 can set the determination threshold of the harmonic content of each wide-band measurement device 20 as needed, so as to play the management and leading role of the wide-band measurement master station 30 in the overall system.

In one embodiment, the wide-band measurement device 20 is further configured to sample the electrical signal, obtain the waveform sequence corresponding to the electrical signal, and upload the waveform sequence to the wide-band measurement master station 30. In particular, the wide-band measurement master station 30 can subscribe the required data in each wide-band measurement device 20, and one of the subscribed topics is the waveform data of the electrical signal. The electrical signal output by the signal sensing module 10 to the wide-band measurement device 20 is an analog quantity, which is not conducive to the remote transmission of the wide-band measurement device 20 to the wide-band measurement master station 30. Therefore, the wide-band measurement device 20 can sample the electrical signal through the A/D sampling module configured therein, and generate the waveform sequence corresponding to the current signal and the voltage signal respectively. The waveform sequence is a digital quantity and can be transmitted with higher communication quality and lower communication delay. In addition, the long-term sampling work has a heavy workload on the wide-band measurement device 20. It may be an option to periodically transmit the waveform sequence corresponding to the electrical signal to the wide-band measurement master station 30, or to transmit the waveform sequence corresponding to the electrical signal under the instruction of the wide-band measurement master station 30.

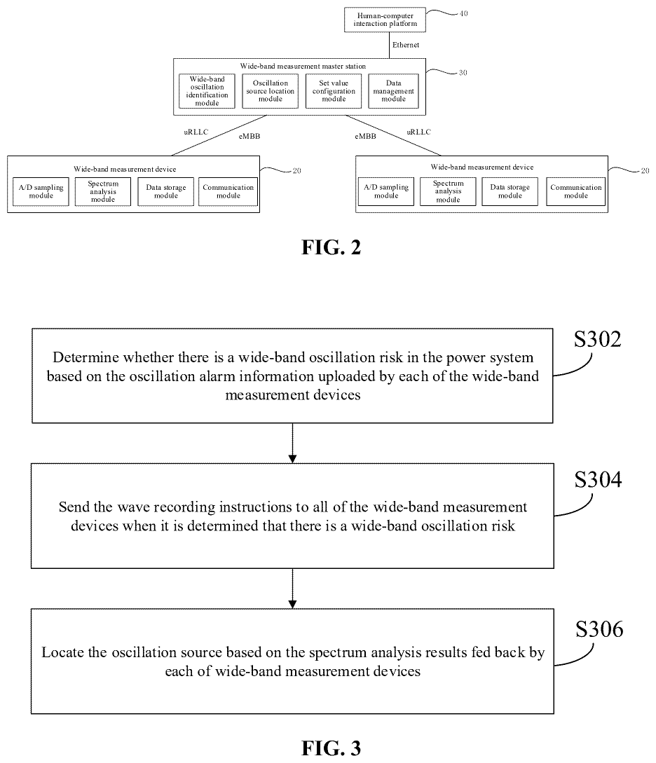

In one embodiment, the wide-band measurement master station 30 is communicatively connected to each wide-band measurement device 20 through 5G network. Due to the scarce communication resources, and the high construction cost and difficult maintenance of communication networks such as optical fiber and cable in many subdivided scenarios of the power system, especially in offshore wind power scenarios, the wide-area monitoring for wide-band oscillation is required. Therefore, the embodiment designs a special communication architecture to address this issue. As shown in FIG. 2, the uRLLC (Ultra-Reliable Low-Latency Communication) protocol and the eMBB (Enhanced Mobile Broadband) protocol are two different protocols for 5G application scenario. The characteristics of the uRLLC protocol are high reliability, low latency, and extremely high availability. The spectrum analysis results, waveform sequences, and wave recording instructions in this embodiment are generally required to be transmitted between the wide-band measurement master station 30 and the wide-band measurement device 20 when there is a wide-band oscillation risk in the system, which have high requirements on delay. Therefore, the uRLLC protocol with matched characteristics is selected for transmission. The eMBB protocol is characterized by high speed, high capacity, and high density. The volume of the wave recording files is large, while the content threshold has low requirements for latency, so it is chosen to be transmitted through the eMBB protocol.

The embodiment of the present disclosure provides a method for locating the source of wide-band oscillation, which is applied to the wide-band measurement master station in the wide-area monitoring system for wide-band oscillation as described in any of the above embodiments. Referring to FIG. 3, the method for locating the source of wide-band oscillation includes steps S302 to S306.

S302: Determining whether there is a wide-band oscillation risk in the power system based on the oscillation alarm information uploaded by each of the wide-band measurement devices.

It can be understood that when the wide-band measurement master station receives an oscillation alarm information, it means that there is a harmonic oscillation at a certain measured point. However, from the perspective of the entire power system, only when multiple measured points report alarms can it be determined that there is a wide-band oscillation risk in the power system. Specifically, a determination ratio can be set in the set value configuration module. The wide-band measurement master station determines the determination threshold based on the number of the wide-band measurement devices currently online and the determination ratio. When the number of the received oscillation alarm information exceeds the determination threshold, the wide-band measurement master station determines that the power system has a wide-band oscillation risk. For example, when there are 5 wide-band measurement devices online and the determination ratio is 40%, when three or more oscillation alarm information are received, it can be determined that the power system has a wide-band oscillation risk.

S304: When it is determined that there is a wide-band oscillation risk, sending the wave recording instruction to all of the wide-band measurement devices. The wave recording instruction is used to instruct the wide-band measurement device to perform wave recording on the electrical signal output by the signal sensing module connected thereto, generate the wave recording files for the same time section and upload the wave recording files and spectrum analysis results to the wide-band measurement master station.

It can be understood that the wave recording files can record the waveform and data of some fault-related characteristic quantities in the power system when the oscillation fault occurs. Generally speaking, in addition to the waveforms of the current signal and the voltage signal, the wave recording files also record data related to the action sequence, system frequency, active power, reactive power, negative sequence current, zero sequence current, negative sequence voltage, zero sequence voltage, etc. of the protection and safety automatic devices. These data can be used to analyze the process, impact of harmonic oscillation and the action of protection devices and so on. However, the spectrum analysis results are the input of the traceability algorithm set in the wide-band measurement master station. Therefore, when it is determined that there is a wide-band oscillation risk in the power system, it is necessary to obtain the spectrum analysis results from the wide-band measurement device and store the wave recording file to facilitate later fault analysis.

S306: Locating the oscillation source based on the spectrum analysis results fed back by each of the wide-band measurement devices.

In one embodiment, locating the oscillation source based on the spectrum analysis results fed back by each of the wide-band measurement devices, including:

(1) Performing data concatenation on the spectrum analysis results fed back by each of the wide-band measurement devices to obtain a wide-area wide-band spectrum information set.

That is, the spectrum analysis results fed back by each of the wide-band measurement devices are formed into a data set. According to the topological connection relationship between the measured points corresponding to each of the wide-band measurement devices, the data concatenation can be performed on the spectrum analysis results fed back by each of the wide-band measurement devices to obtain a wide-area wide-band spectrum information set. Specifically, in the database, the spectrum analysis results fed back by different wide-band measurement devices can be marked according to the connection relationship between the measured points corresponding to the different wide-band measurement devices, this allows for a better integration with the grid structure of the power grid during operations such as data queries and index creation.

(2) Locating the oscillation source according to the wide-area wide-band spectrum information set.

In one embodiment, locating the oscillation source according to the wide-area wide-band spectrum information set, including:

(1) Traversing the target harmonics in the target frequency band range.

The target frequency band range is the frequency band range that needs to be detected in wide-area monitoring for wide-band oscillations. The frequency band within 2500 Hz can be selected as the target frequency band range. The target harmonic refers to a harmonic of a specific order related to the harmonic oscillation within the target frequency band range. There can be one or more target harmonics in the target frequency band range, and the oscillation source location of harmonics with different orders may be different. Therefore, it is necessary to traverse the target harmonics in the target frequency band range.

(2) For the current target harmonic, selecting any one node from the nodes of the power system as the target node.

The current target harmonic refers to the target harmonic traversed in this round. The topological diagram abstracted based on the actual structure of the power system is generally composed of nodes and lines. The nodes in the power system are generally the collection points of current or the collection points of branches in the power grid calculation and analysis. They generally correspond to the bus bar, etc. of the power grid. In order to trace the source in the power system, firstly, any one of the nodes is selected from the power system as the starting node and tracing the source starts from this node.

(3) Performing Norton equivalence on the power system based on the target node.

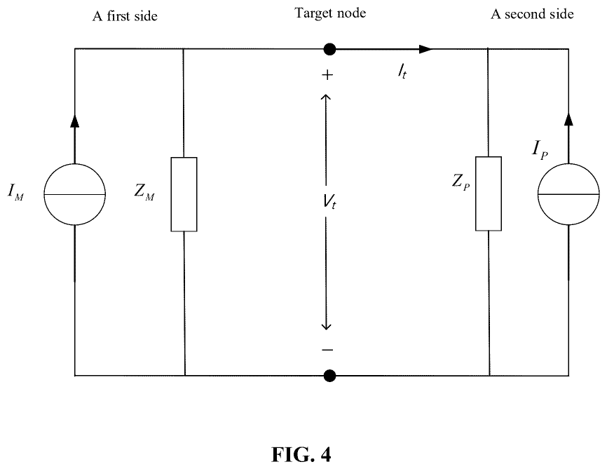

It can be understood that the systems on the first and second sides of the target node are respectively equivalent to a structure in which a current source and an impedance are connected in parallel, with the two point locations of the target node and the ground terminal as endpoints. Please refer to FIG. 4, where Vₜ represents the voltage of the target node, Vₜ represents the voltage of the target node at the target harmonic frequency, and Iₜ represents the current of the target node at the target harmonic frequency. I_{M} represents the current of the Norton equivalent current source on the first side of the target node at the target harmonic frequency, and Z_{M} represents the impedance of the Norton equivalent current source on the first side of the target node at the target harmonic frequency. I_{P} represents the current of the Norton equivalent current source on the second side of the target node at the target harmonic frequency, and Z_{P} represents the impedance of the Norton equivalent current source on the second side of the target node at the target harmonic frequency.

(4) Based on the equivalent model, determining the first equivalent impedance on the first side and the second equivalent impedance on the second side of the target node.

It can be understood that since the grid structure of the power system is known, the magnitude of the equivalent impedances on both sides of the target node can be analyzed respectively, i.e., the magnitude of the first equivalent impedance and the second equivalent impedance can be determined. In addition, it is worth mentioning that since this embodiment analyzes target harmonic of a specific order, when obtaining the expressions for the first equivalent impedance and the second equivalent impedance, the specific values of the first equivalent impedance and the second equivalent impedance should be calculated based on the frequency of the target harmonic, as the capacitive reactance and inductive reactance in the impedance are related to the frequency.

(5) Determining a first current and a second current according to the wide-area wide-band spectrum information set, the first current is defined as a current component of the target harmonic on the first side of the target node, and the second current is defined as a current component of the target harmonic on the second side of the target node, and.

It can be understood that the measured points in the power system include both sides of each node of the power system, and the wide-area wide-band spectrum information set includes the current components corresponding to each harmonic of the measured point within the target frequency band range, and the current of the Norton equivalent current source on the first side of the target node is equal to the first current, and the current of the Norton equivalent current source on the second side of the target node is equal to the second current. The first current and the second current can be extracted from the wide-area wide-band spectrum information set.

(6) Determine an inflow side of oscillation power of the target harmonic as the first side or the second side, according to the first current, the first equivalent impedance, the second current and the second equivalent impedance.

It can be understood that the active power flow method adopted in the disclosure has a clear physical meaning, simple calculation, good effect, and is suitable for online identification of the sources of wide-band oscillation. Specifically, at the frequency of the target harmonic, by determining whether the active power flows in or out at the target node, it can be determined whether the oscillation source at the frequency of the target harmonic is located on the first side or the second side. The active power Pₜ of the target node at the frequency of the target harmonic can be expressed as:

$${P}_{t} = Re [ {V}_{t} \cdot {I}_{t}^{*} ] = \vert {I}_{P} {Z}_{P} \vert - \vert {I}_{M} {Z}_{M} \vert$$

From this equation, it can be concluded that when Pₜ is greater than 0, the oscillation active power flows into the target node from the second side, i.e., the oscillation source is located on the second side. When Pₜ is less than 0, the oscillation active power flows into the target node from the first side, i.e., the oscillation source is located on the first side. Based on this, the product of the first current and the first equivalent impedance is determined as the first product; the product of the second current and the second equivalent impedance is determined as the second product; when the absolute value of the first product is greater than the absolute value of the second product, the inflow side is determined to be the first side; when the absolute value of the first product is less than the absolute value of the second product, the inflow side is determined to be the second side.

(7) Determining whether the inflow side corresponding to the current target node has changed from the inflow side corresponding to a previous target node.

(8) When the inflow side corresponding to the current target node has not changed from the inflow side corresponding to the previous target node, determining a node connected to the current target node on the inflow side as a new target node, and returning to step of performing Norton equivalence on the power system based on the target node to proceed.

(9) When the inflow side corresponding to the current target node has changed from the inflow side corresponding to a previous target node, determining that the source of oscillation of the target harmonic is located between the current target node and the previous target node.

It can be understood that in this embodiment, the oscillation source is approached gradually against the flow direction of active power, and finally the oscillation source is located. The inflow side corresponding to the current target node has not changed from the inflow side corresponding to the previous target node, it represents that the active power is transmitted from the same side of the current target node and the previous target node, which means that the oscillation source has not yet been passed during the tracing process. It is necessary to continue to trace against the flow direction of active power, i.e., to determine the node connected to the current target node on the inflow side as the new target node, and return to step (3) to continue tracing. When it is found that the inflow side has changed, it can be determined that the oscillation source has been passed. Therefore, it can be determined that the oscillation source is between the current target node and the previous target node, and the oscillation source can be located.

The various embodiments in this specification are described in a progressive way, with each embodiment emphasizing its differences from other embodiments. The embodiments may be combined as needed, and the same or similar parts may be referred to each other.

The above description of the disclosed embodiments enables those skilled in the art to implement or use the present disclosure. Various modifications to these embodiments will be obvious to those skilled in the art. The general principle defined herein may be applied to other embodiments without departing from the spirit or scope of the present disclosure. Therefore, the present disclosure is not limited to the embodiments illustrated herein, but should conform to the widest scope consistent with the principle and novel features disclosed herein.

What is claimed is:

1. A wide-area monitoring system for wide-band oscillation, comprising:
a plurality of signal sensing modules, which are configured to acquire electric signals of measured points;
a plurality of wide-band measurement devices, which are connected to the signal sensing modules, and are configured to perform spectrum analysis based on the electrical signals acquired by each of the signal sensing modules and generate oscillation alarm information based on spectrum analysis results, and are also configured to start wave recording in response to wave recording instructions, to generate wave recording files for a same time section, and upload the wave recording files and the spectrum analysis results; and
a wide-band measurement master station, which is communicatively connected to each of the wide-band measurement devices, and is configured to determine whether there is a wide-band oscillation risk in a power system based on the oscillation alarm information uploaded by each of the wide-band measurement devices, send the wave recording instructions to all of the wide-band measurement devices when it is determined that there is the wide-band oscillation risk, and locate an oscillation source based on the spectrum analysis results fed back by each of the wide-band measurement devices.

2. The wide-area monitoring system for wide-band oscillation according to claim 1, wherein the wide-band measurement devices are configured to determine a content of each harmonic in the electrical signals based on the spectrum analysis results, and generate the oscillation alarm information when the content exceeds a corresponding content threshold, and send the oscillation alarm information to the wide-band measurement master station.

3. The wide-area monitoring system for wide-band oscillation according to claim 2, wherein the wide-band measurement master station is configured to send the content threshold to each of the wide-band measurement devices.

4. The wide-area monitoring system for wide-band oscillation according to claim 3, wherein the wide-band measurement devices are further configured to sample the electrical signals to obtain a waveform sequence corresponding to the electrical signals, and upload the waveform sequence to the wide-band measurement master station.

5. The wide-area monitoring system for wide-band oscillation according to claim 4, wherein the wide-band measurement master station is communicatively connected to each of the wide-band measurement devices through a 5G network, the spectrum analysis results, the waveform sequence and the wave recording instructions are transmitted through an uRLLC protocol, and the wave recording files and the content threshold are transmitted through an eMBB protocol.

6. A method for locating a source of wide-band oscillation, applied to the wide-band measurement master station in the wide-area monitoring system for wide-band oscillation according to claim 1, comprising:
determining whether there is the wide-band oscillation risk in the power system based on the oscillation alarm information uploaded by each of the wide-band measurement devices;
sending the wave recording instructions to all of the wide-band measurement devices when it is determined that there is the wide-band oscillation risk, wherein the wave recording instruction is to instruct the wide-band measurement devices to perform wave recording to generate the wave recording files for the same time section, and upload the wave recording files and the spectrum analysis results to the wide-band measurement master station; and
locating the oscillation source based on the spectrum analysis results fed back by each of the wide-band measurement devices.

7. The method for locating the source of wide-band oscillation according to claim 6, wherein determining whether there is the wide-band oscillation risk in the power system based on the oscillation alarm information uploaded by each of the wide-band measurement devices comprises:
determining that there is the wide-band oscillation risk in the power system when an amount of the received oscillation alarm information is greater than a determination threshold.

8. The method for locating the source of wide-band oscillation according to claim 6, wherein locating the oscillation source based on the spectrum analysis results fed back by each of the wide-band measurement devices comprises:
performing data concatenation on the spectrum analysis results fed back by each of the wide-band measurement devices to obtain a wide-area wide-band spectrum information set; and
locating the oscillation source based on the wide-area wide-band spectrum information set.

9. The method for locating the source of wide-band oscillation according to claim 8, wherein performing data concatenation on the spectrum analysis results fed back by each of the wide-band measurement devices to obtain the wide-area wide-band spectrum information set comprises:
performing data concatenation on the spectrum analysis results fed back by each of the wide-band measurement devices according to topological connection relationship between the measured points corresponding to each of the wide-band measurement devices, to obtain the wide-area wide-band spectrum information set.

10. The method for locating the source of wide-band oscillation according to claim 8, wherein locating the oscillation source based on the wide-area wide-band spectrum information set comprises:
traversing each target harmonic in a target frequency band range;
for a current target harmonic, selecting any one node from nodes in the power system as a target node;
performing Norton equivalence on the power system based on the target node;
determining, based on an equivalent model, a first equivalent impedance on a first side and a second equivalent impedance on a second side of the target node;
determining a first current and a second current based on the wide-area wide-band spectrum information set, the first current is defined as a current component of the target harmonic on the first side of the target node, and the second current is defined as a current component of the target harmonic on the second side of the target node;
determining an inflow side of oscillation power of the target harmonic as the first side or the second side, based on the first current, the first equivalent impedance, the second current, and the second equivalent impedance;
determining whether the inflow side corresponding to the current target node has changed from the inflow side corresponding to a previous target node;
when the inflow side corresponding to the current target node has not changed from the inflow side corresponding to the previous target node, determining a node connected to the current target node on the inflow side as a new target node, and returning to step of performing Norton equivalence on the power system based on the target node to proceed; and
when the inflow side corresponding to the current target node has changed from the inflow side corresponding to the previous target node, determining that the oscillation source of the target harmonic is located between the current target node and the previous target node.

11. The method for locating the source of wide-band oscillation according to claim 10, wherein determining the inflow side of oscillation power of the target harmonic as the first side or the second side, based on the first current, the first equivalent impedance, the second current, and the second equivalent impedance comprises:
determining a product of the first current and the first equivalent impedance as a first product;
determining a product of the second current and the second equivalent impedance as a second product;
when an absolute value of the first product is greater than an absolute value of the second product, determining the inflow side as the first side; and
when the absolute value of the first product is smaller than the absolute value of the second product, determining the inflow side as the second side.
